(19) United States
(12) Patent Application Publication
(10) Pub. No.: US 2026/0198327 A1
(43) Pub. Date: Jul. 9, 2026

(54) SEMICONDUCTOR PACKAGE WITH TOP-LID SURFACE-MOUNTED TECHNOLOGY CAPACITORS FOR ENHANCED PERFORMANCE

(71) Applicant: Qorvo US, Inc., Greensboro, NC (US)

(72) Inventor: Assaf Aviv Haviv, Frisco, TX (US)

(21) Appl. No.: 19/413,709

(22) Filed: Dec. 9, 2025

Related U.S. Application Data
(60) Provisional application No. 63/742,116, filed on Jan. 6, 2025.

(51) Int. Cl. H10W 42/20; H10W 44/20; H10W 76/01; H10W 76/153; H10W 90/10

(52) U.S. Cl. CPC H10W 42/276; H10W 44/243; H10W 76/01; H10W 76/153; H10W 90/10

(57) ABSTRACT

Aspects of the disclosure provide a semiconductor package and a method for preparing the same. The disclosed semiconductor package includes a die disposed on a laminate; an interposer disposed between the die and the laminate, the interposer comprising a plurality of vias configured for electrical connections between the die and the laminate; a lid attached to the interposer via one or more legs of the lid in a configuration such that the attachment forms an encapsulation that encapsulates the die therewithin; and one or more capacitive or passive components electrically connected to the laminate. In one or more embodiments, the one or more capacitive or passive components are surface-mounted technology (SMT) decoupling capacitors, radio frequency (RF) tuning capacitors, and/or other passive components. In one or more embodiments, a wireless device may include the semiconductor package produced via the method as disclosed herein.

### CROSS-REFERENCE TO RELATED APPLICATION

This application claims priority to U.S. Patent Application No. 63/742,116, filed January 6, 2025, all of which is incorporated by reference herein in its entirety.

### TECHNICAL FIELD

The present disclosure relates generally to semiconductor manufacturing methodologies and related implementations, and in particular, relates to systems and methods for preparing a semiconductor package having surface-mounted technology (SMT) decoupling capacitive or passive components within the semiconductor package.

### BACKGROUND

Advanced semiconductor electronics are typically assembled using cutting-edge manufacturing techniques. As known in the industry, dies in semiconductor packages require decoupling capacitive or passive components to stabilize the direct current inputs and minimize noise during operation. Traditionally, these capacitive or passive components are placed outside the package, either on the printed circuit board (PCB) close to the die or on the underside of the board directly under the die. However, with the advancement of integrated circuit technology toward higher frequencies and shrinking device sizes, there is an increasing demand for reducing the overall package size and footprint while maintaining or improving performance.

Currently, capacitive or passive components placed outside the package occupy valuable board space and complicate PCB layout. Additionally, placing capacitive or passive components on the opposite side of the board requires double-sided assembly, increasing manufacturing complexity and cost. Moreover, there is a growing need to place multiple semiconductor packages in close proximity on the same board while ensuring electromagnetic interference (EMI) shielding for each package. Thus, there is a need for a solution that reduces the footprint of the semiconductor package on the board while also allowing for the integration of decoupling capacitive or passive components without the drawbacks of traditional approaches.

### SUMMARY

Embodiments of the present disclosure include advanced semiconductor manufacturing methodologies for preparing a semiconductor package having surface-mounted technology (SMT) decoupling capacitive or passive components within the semiconductor package. Aspects of the disclosure advantageously provide a semiconductor package and one or more methods of preparing a semiconductor package for use in wireless devices, wireless communications, and/or radar systems.

In an exemplary aspect, a semiconductor package is provided. The semiconductor package includes a die disposed on a laminate; an interposer disposed between the die and the laminate, the interposer comprising a plurality of vias configured for electrical connections between the die and the laminate; a lid attached to the interposer via one or more legs of the lid in a configuration such that the attachment forms an encapsulation that encapsulates the die therewithin; and one or more capacitive or passive components electrically connected to the laminate.

In one or more embodiments, the one or more capacitive or passive components are surface-mounted technology (SMT) decoupling capacitors, radio frequency (RF) tuning capacitors, and/or other passive components. In one or more embodiments, the one or more capacitive or passive components are disposed atop the lid and are electrically connected to the laminate via one or more electrical connections embedded within the one or more legs of the lid. In one or more embodiments, the one or more electrical connections embedded within the one or more legs of the lid comprise conductive vias. In one or more embodiments, the conductive vias are formed within the one or more legs, through silicon vias, metal posts, or plated through-holes, etc. In one or more embodiments, the one or more capacitive or passive components are disposed on the laminate adjacent the interposer.

In one or more embodiments, the semiconductor package may further include an electromagnetic interference (EMI) shield structure (also referred to herein as a conductive shielding structure) attached to the laminate via one or more legs of the EMI shield structure such that the attachment forms an EMI shield that shields the die therewithin. In one or more embodiments, the one or more capacitive or passive components are disposed atop the lid and are electrically connected to the laminate via one or more electrical connections embedded within the one or more legs of the lid.

In one or more embodiments, the die is a first die, the semiconductor package may further include a second die disposed on the laminate, adjacent the first die; and an electromagnetic interference (EMI) shield structure attached to the laminate via one or more legs of the EMI shield structure such that the attachment forms an EMI shield that shields the first die and the second die therewithin, wherein the one or more capacitive or passive components are disposed on the laminate adjacent the interposer.

In an exemplary aspect, a method for preparing a semiconductor package is provided. The method may include disposing an interposer on a laminate; disposing a die atop the interposer, wherein the interposer comprises a plurality of vias configured for electrical connections between the die and the laminate; attaching a lid to the interposer via one or more legs of the lid in a configuration such that the attachment forms an encapsulation that encapsulates the die therewithin; and electrically connecting one or more capacitive or passive components to the laminate.

In one or more embodiments, the one or more capacitive or passive components are surface-mounted technology (SMT) decoupling capacitors, radio frequency (RF) tuning capacitors, and/or other passive components. In one or more embodiments, electrically connecting one or more capacitive or passive components to the laminate comprises disposing the one or more capacitive or passive components atop the lid, and electrically connecting the one or more capacitive or passive components to the laminate via one or more electrical connections embedded within the one or more legs of the lid. In one or more embodiments, the one or more electrical connections embedded within the one or more legs of the lid comprise conductive vias. In one or more embodiments, the conductive vias are formed within the one or more legs, through silicon vias, metal posts, or plated through-holes, etc. In one or more embodiments, the one or more capacitive or passive components are disposed on the laminate adjacent the interposer.

In one or more embodiments, the method further includes, optionally, attaching an electromagnetic interference (EMI) shield structure to the laminate via one or more legs of the EMI shield structure such that the attachment forms an EMI shield that shields the die therewithin. In one or more embodiments, the one or more capacitive or passive components are disposed atop the lid and are electrically connected to the laminate via one or more electrical connections embedded within the one or more legs of the lid.

In one or more embodiments, the die is a first die, the method further includes disposing a second die on the laminate, adjacent the first die; and attaching an electromagnetic interference (EMI) shield structure to the laminate via one or more legs of the EMI shield structure such that the attachment forms an EMI shield that shields the first die and the second die therewithin. In one or more embodiments of the method, the one or more capacitive or passive components are disposed on the laminate adjacent the interposer.

In an exemplary aspect, a wireless device comprising a semiconductor package is provided. The semiconductor package of the wireless device includes a die disposed on a laminate; an interposer disposed between the die and the laminate, the interposer comprising a plurality of vias configured for electrical connections between the die and the laminate; a lid attached to the interposer via one or more legs of the lid in a configuration such that the attachment forms an encapsulation that encapsulates the die therewithin; and one or more surface-mounted technology (SMT) decoupling capacitors, radio frequency (RF) tuning capacitors, and/or other passive components electrically connected to the laminate.

In one or more embodiments of the wireless device, the one or more capacitive or passive components are disposed atop the lid and are electrically connected to the laminate via one or more electrical connections embedded within the one or more legs of the lid.

In one or more embodiments of the wireless device, the semiconductor package further includes an electromagnetic interference (EMI) shield structure attached to the laminate via one or more legs of the EMI shield structure such that the attachment forms an EMI shield that shields the die therewithin.

In one or more embodiments of the wireless device, the die is a first die, the semiconductor package further includes a second die disposed on the laminate, adjacent the first die; and an electromagnetic interference shield structure attached to the laminate via one or more legs of the EMI shield structure such that the attachment forms an EMI shield that shields the first die and the second die therewithin, wherein the one or more capacitive or passive components are disposed on the laminate adjacent the interposer.

Additional aspects, embodiments, implementations, features, and advantages of the present disclosure will become apparent from the following detailed description.

### BRIEF DESCRIPTION OF THE DRAWINGS

Illustrative embodiments of the present disclosure will be described with reference to the accompanying drawings, of which:

FIG. 1 illustrates a cross-sectional view of an example semiconductor package, according to aspects of the present disclosure.

FIG. 2 illustrates a cross-sectional view of an example semiconductor package, according to aspects of the present disclosure.

FIG. 3 illustrates a cross-sectional view of an example semiconductor package, according to aspects of the present disclosure.

FIG. 4 illustrates a cross-sectional view of an example semiconductor package, according to aspects of the present disclosure.

FIG. 5 illustrates a flowchart for a method for preparing an example semiconductor package, according to aspects of the present disclosure.

FIG. 6 illustrates an electronic device or a wireless device comprising a semiconductor package, according to aspects of the present disclosure.

### DETAILED DESCRIPTION

For the purposes of promoting an understanding of the principles of the present disclosure, reference will now be made to the embodiments illustrated in the drawings, and specific language will be used to describe the same. It is nevertheless understood that no limitation to the scope of the disclosure is intended. Any alterations and further modifications to the described devices, systems, and methods, and any further application of the principles of the present disclosure are fully contemplated and included within the present disclosure as would normally occur to one skilled in the art to which the disclosure relates. In particular, it is fully contemplated that the features, components, and/or steps described with respect to one embodiment may be combined with the features, components, and/or steps described with respect to other embodiments of the present disclosure. For the sake of brevity, however, the numerous iterations of these combinations will not be described separately.

Embodiments of the present disclosure include advanced semiconductor manufacturing methodologies for preparing a semiconductor package with minimal footprint on the PCB while allowing for the integration of decoupling capacitive or passive components without the drawbacks of traditional approaches. The disclosed semiconductor package may include surface-mounted technology (SMT) decoupling capacitive or passive components that are disposed atop a lid or adjacent a die or an interposer within the semiconductor package. The disclosed semiconductor package implementation aims to minimize footprint on the PCB while allowing for the integration of SMT decoupling capacitive or passive components without the drawbacks of traditional approaches. The disclosed semiconductor package implementation can enable placing multiple semiconductor packages in close proximity on the same board while ensuring electromagnetic interference (EMI) shielding for each package.

In accordance with one or more embodiments, the disclosed semiconductor packaging methodologies using SMT decoupling capacitive or passive components is designed to be integrated directly into the packaging of semiconductor devices. In accordance with one or more embodiments, the disclosed method includes placing SMT decoupling capacitive or passive components on top of a lid that covers the semiconductor die within the package.

The disclosed semiconductor package offers several advantages, including a reduced package footprint, a simplified assembly, and improved EMI shielding capabilities, which provide enhanced performance suitable for high-frequency applications. For example, by placing the decoupling capacitive or passive components on top of the lid, the overall board space required for the package is minimized. This reduction allows multiple packages to be placed in closer proximity on the board, making it ideal for high-density applications. The simplified assembly enables the assembly of all components on one side of the board, eliminating the need for double-sided assembly and reducing manufacturing complexity. The improved EMI shielding allows for an integrated lid design that facilitates the inclusion of an EMI shield around the package, as the capacitive or passive components are within the footprint of the package and do not protrude onto the PCB. These overall advantages lead to a more enhanced performance suitable for high-frequency applications by placing the capacitive or passive components next to the die, which in turns, minimizes parasitic inductance and resistance, which may be critical for maintaining performance in high-frequency applications. The disclosed semiconductor package includes any integrated circuit that can be used with on-package decoupling or passive components, and materials listed herein are non-limiting examples.

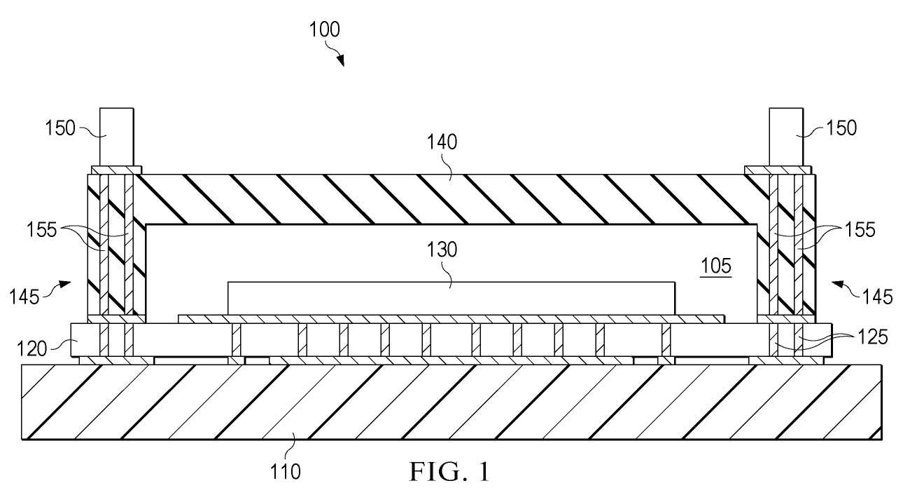

Various embodiments of the disclosed packaging and methodologies are described below in further detail with respect to FIGS. 1-6.

FIG. 1 illustrates a cross-sectional view of an example semiconductor package 100, according to aspects of the present disclosure. In one or more embodiments, the semiconductor package 100 may include a wide band gap semiconductor package with advanced semiconductor manufacturing. In some embodiments, the semiconductor package 100 may be produced or manufactured using advanced semiconductor packaging techniques as disclosed herein.

As illustrated in FIG. 1, the semiconductor package 100 includes a laminate 110, which may comprise an organic composite, in accordance with one embodiment. The semiconductor package 100 includes an interposer 120 disposed atop, or attached to, the laminate 110. In one or more embodiments, the interposer 120 comprises an electrically-insulating material. In one or more embodiments, the interposer 120 may include silicon carbide, silicon, gallium nitride, aluminum nitride, alumina, glass-ceramic, or an organic composite.

As further illustrated in FIG. 1, the semiconductor package 100 includes a die 130 disposed atop, or attached to, the interposer 120. In one or more embodiments, the die 130 may include a radio frequency monolithic microwave integrated circuit. In one or more embodiments, the die 130 may be configured to operate in a range of frequency between 50 GHz and 150 GHz, between 70 GHz and 130 GHz, between 90GHz and 110 GHz, or any frequence ranges therebetween.

In one or more embodiments, the interposer 120 may include a plurality of vias 125 (also referred to herein as hot vias), which are vertical through-vias across the thickness of the interposer 120. In various embodiments, the vias 125 are configured for electrical connections between the die 130 and the laminate 110, as shown in FIG. 1. In one or more embodiments, one or more of the vias 125 may be electrically connected to one or more hot vias (not shown) of the die 130.

As further illustrated in FIG. 1, the semiconductor package 100 includes a lid 140 attached to the interposer 120. In one or more embodiments, the lid 140 is attached to the interposer 120 via one or more legs 145 of the lid 140 in a configuration such that the attachment forms an encapsulation that encapsulates the die 130 therewithin. In one or more embodiments, the lid 140 comprises a ceramic or semiconductor material. In one or more embodiments, the lid 140 may include silicon carbide, silicon, gallium nitride, aluminum nitride, alumina, glass-ceramic, or an organic composite. In one or more embodiments, the lid 140 may be attached to the interposer 120 in a configuration, as shown in FIG. 1, such that the attachment forms a cavity 105 that encapsulates the die 130 therewithin.

In one or more embodiments, the semiconductor package 100 includes one or more capacitive or passive components 150 electrically connected to the laminate 110. In one or more embodiments, the one or more capacitive or passive components 150 are surface-mounted technology (SMT) decoupling capacitors, radio frequency (RF) tuning capacitors, and/or other passive components. In one or more embodiments, the one or more capacitive or passive components 150 are disposed atop the lid 140 and are electrically connected to the laminate 110 via one or more electrical connections 155 embedded within the one or more legs 145 of the lid 140, as shown in FIG. 1. In other words, the lid 140 comprises one or more conductive structures (e.g., shown as one or more electrical connections 155 embedded within the one or more legs 145) extending through the structure of the lid 140, in one or more embodiments. In one or more embodiments, the one or more electrical connections 155 embedded within the one or more legs 145 of the lid 140 are conductive vias, which are configured for electrical connections between the one or more capacitive or passive components 150 and the laminate 110. In one or more embodiments, the conductive vias are formed within the one or more legs, through silicon vias, metal posts, or plated through-holes, etc. In other words, the vias 125 provide a direct electrical path from the one or more capacitive or passive components 150 to the die 130's power and ground inputs, ensuring minimal signal degradation. By placing the one or more capacitive or passive components 150 on the lid 140, the semiconductor package 100 eliminates the need to allocate separate board (e.g., PCB) space for decoupling capacitive or passive components, as they are now part of the semiconductor package 100 itself.

In one or more embodiments, the semiconductor package 100 includes the die 130 disposed on the laminate 110, the lid 140 attached to the laminate 110 via one or more legs 145 of the lid 140 in a configuration such that the attachment forms an encapsulation that encapsulates the die 130 therewithin, and one or more capacitive or passive components 150 electrically connected to the laminate 110.

In one or more embodiments, the one or more capacitive or passive components 150 are surface-mounted technology (SMT) decoupling capacitors, radio frequency (RF) tuning capacitors, and/or other passive components. In one or more embodiments, the one or more capacitive or passive components 150 are disposed atop the lid 140 and are electrically connected to the laminate 110 via one or more electrical connections 155 embedded within the one or more legs 145 of the lid 140. In one or more embodiments, the one or more electrical connections 155 embedded within the one or more legs 145 of the lid 140 comprise conductive vias. In one or more embodiments, the conductive vias are formed within the one or more legs, through silicon vias, metal posts, or plated through-holes, etc. In one or more embodiments, the one or more capacitive or passive components 150 are disposed on the laminate.

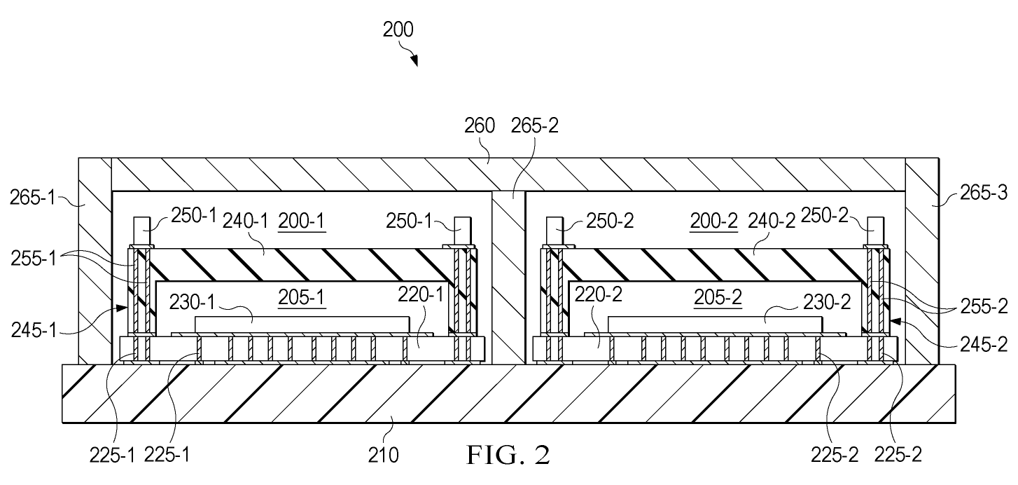

Now referring to FIG. 2, which illustrates a cross-sectional view of an example semiconductor package 200, according to aspects of the present disclosure. In one or more embodiments, the semiconductor package 200 may include a wide band gap semiconductor package with advanced semiconductor manufacturing. In some embodiments, the semiconductor package 200 may be produced or manufactured using advanced semiconductor packaging techniques as disclosed herein.

As illustrated in FIG. 2, the semiconductor package 200 includes a laminate 210, which may comprise an organic composite, in accordance with one embodiment. The semiconductor package 200 includes a first interposer 220-1 and a second interposer 220-2 (collectively may be referred to herein as interposers 220) disposed atop, or attached to, the laminate 210. In one or more embodiments, each of the interposers 220-1 and 220-2 may include silicon carbide. Although shown with two interposers 220-1 and 220-2 in FIG. 2, the semiconductor package 200 may include any number of interposers 220 within the semiconductor package 200.

As further illustrated in FIG. 2, the semiconductor package 200 includes a first die 230-1 and a second die 230-2 (collectively may be referred to herein as dies 230) disposed atop, or attached to, the respective first interposer 220-1 and second interposer 220-2. Although shown with two dies 230-1 and 230-2 in FIG. 2, the semiconductor package 200 may include any number of dies 230 within the semiconductor package 200. In one or more embodiments, the dies 230 may include a radio frequency monolithic microwave integrated circuit. In one or more embodiments, the dies 230 may be configured to operate in a range of frequency between 50 GHz and 150 GHz, between 70 GHz and 130 GHz, between 90 GHz and 110 GHz, or any frequence ranges therebetween.

In one or more embodiments, the interposers 220-1 and 220-2 may include a plurality of vias 225-1 and 225-2 (collectively may be referred to herein as vias 225), respectively (also referred to herein as hot vias), which are vertical through-vias across the thickness of the interposers 220-1 and 220-2. In various embodiments, the vias 225-1 and 225-2 are configured for electrical connections between the dies 230 and the laminate 210, as shown in FIG. 2. In one or more embodiments, one or more of the vias 225-1 and 225-2 may be electrically connected to one or more hot vias (not shown) of the dies 230.

As further illustrated in FIG. 2, the semiconductor package 200 includes a first lid 240-1 and a second lid 240-2 (collectively may be referred to herein as lids 240) respectively attached to the first interposer 220-1 and the second interposer 220-2. In one or more embodiments, the first lid 240-1 is attached to the first interposer 220-1 via one or more legs 245-1 of the lid 240-1 in a configuration such that the attachment forms an encapsulation that encapsulates the first die 230-1 therewithin. Similarly, the second lid 240-2 is attached to the second interposer 220-2 via one or more legs 245-2 of the second lid 240-2 in a configuration such that the attachment forms an encapsulation that encapsulates the second die 230-2 therewithin, in one or more embodiments. In other words, the lids 240 may be attached to the interposers 220 in a configuration, as shown in FIG. 2, such that the attachment forms a respective first cavity 205-1 and a second cavity 205-2, which respectively encapsulates the first die 230-1 and the second die 230-2.

In one or more embodiments, the semiconductor package 200 includes one or more first capacitive or passive components 250-1 and one or more second capacitive or passive components 250-2 (collectively may be referred to herein as capacitive or passive components 250) electrically connected to the laminate 210. In one or more embodiments, the one or more capacitive or passive components 250 are surface-mounted technology (SMT) decoupling capacitors, radio frequency (RF) tuning capacitors, and/or other passive components. In one or more embodiments, the one or more capacitive or passive components 250 are disposed atop the lids 240 and are electrically connected to the laminate 210 via one or more electrical connections 255-1 and 255-2 (collectively may be referred to herein as electrical connections 255) embedded within the one or more legs 245-1 and 245-2 (collectively may be referred to herein as legs 245) embedded of the lids 240-1 and 240-2, as shown in FIG. 2. In other words, the lids 240 comprise conductive structures (e.g., shown as electrical connections 255 embedded within the one or more legs 245) extending through the structure of the lid 240, in one or more embodiments. In one or more embodiments, the one or more electrical connections 255 embedded within the one or more legs 245 of the lids 240 are conductive vias, which are configured for electrical connections between the one or more capacitive or passive components 250 and the laminate 210. In one or more embodiments, the conductive vias are formed within the one or more legs, through silicon vias, metal posts, or plated through-holes, etc. In other words, the vias 225 provide a direct electrical path from the one or more capacitive or passive components 250 to the die 230's power and ground inputs, ensuring minimal signal degradation. By placing the one or more capacitive or passive components 250 on the lid 240, the semiconductor package 200 eliminates the need to allocate separate board (e.g., PCB) space for decoupling capacitive or passive components, as they are now part of the semiconductor package 100 itself.

As further illustrated in FIG. 2, the semiconductor package 200 includes an electromagnetic interference (EMI) shield structure 260 (also referred to herein as a conductive shielding structure 260) that is attached to the laminate 210 via one or more legs 265-1, 265-2, and 265-3 (collectively may be referred to herein as legs 265) of the EMI shield structure 260 such that the attachment forms an EMI shield that shields the dies 230 therewithin. As illustrated in FIG. 2, the EMI shield structure 260 forms an EMI shield that shields the first die 230-1 via attachment of the legs 265-1 and 265-2 with the laminate 210. Similarly, the EMI shield structure 260 forms an EMI shield that shields the second die 230-2 via attachment of the legs 265-2 and 265-3 with the laminate 210, as shown in FIG. 2. Thus, a single EMI shield structure 260 is configured to provide an EMI shield to both dies 230-1 and 230-2, in accordance with one or more embodiments. Although shown with legs 265-1, 265-2, and 265-3 in FIG. 2, the EMI shield structure 260 may include any number of legs 265 to provide EMI shielding for any number of dies 230 within the semiconductor package 200. Thus, the disclosed implementation illustrated in FIG. 2 allows the entire semiconductor package 200, including the capacitive or passive components 250, to be covered by a single EMI shield structure 260, which can help reduce electromagnetic interference while improving signal integrity.

In one or more embodiments, the semiconductor package 200 includes one or more of the dies 230 disposed on the laminate 210, one or more of the lids 240 attached to the laminate 210 via one or more of the legs 245 of the lids 240 in a configuration such that the attachment forms an encapsulation that encapsulates the dies 230 therewithin, and one or more capacitive or passive components 250 electrically connected to the laminate 210.

In one or more embodiments, the one or more capacitive or passive components 250 are surface-mounted technology (SMT) decoupling capacitors, radio frequency (RF) tuning capacitors, and/or other passive components. In one or more embodiments, the one or more capacitive or passive components 250 are disposed atop the lids 240 and are electrically connected to the laminate 210 via one or more electrical connections 255 embedded within the one or more legs 245 of the lids 240. In one or more embodiments, the one or more electrical connections 255 embedded within the one or more legs 245 of the lid 240 comprise conductive vias. In one or more embodiments, the conductive vias are formed within the one or more legs, through silicon vias, metal posts, or plated through-holes, etc. In one or more embodiments, the one or more capacitive or passive components 250 are disposed on the laminate 210.

In one or more embodiments, the semiconductor package 200 may further include an electromagnetic interference (EMI) shield structure 260 attached to the laminate 210 via one or more legs 265 of the EMI shield structure 260 such that the attachment forms an EMI shield that shields the dies 230 therewithin. In one or more embodiments, the one or more capacitive or passive components 250 are disposed atop the lids 240 and are electrically connected to the laminate 210 via one or more electrical connections 255 embedded within the one or more legs 245 of the lids 240.

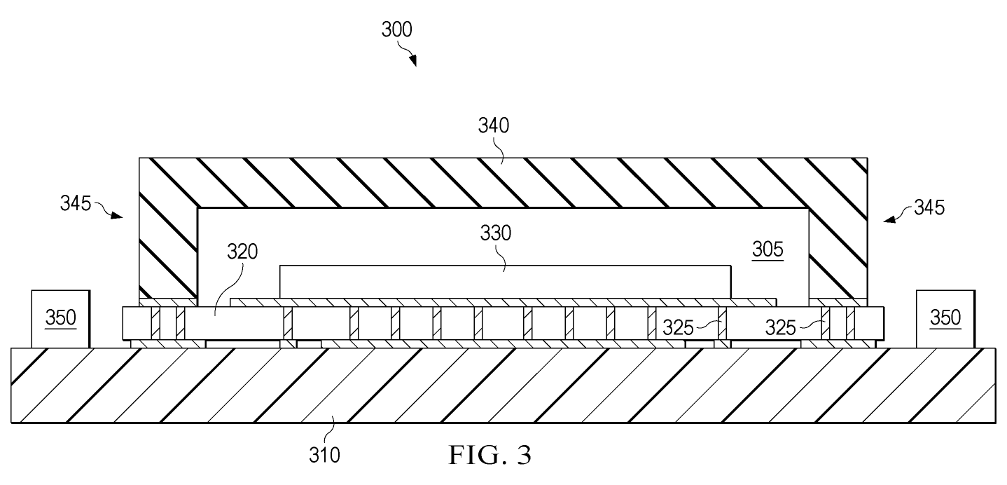

FIG. 3 illustrates a cross-sectional view of an example semiconductor package 300, according to aspects of the present disclosure. In one or more embodiments, the semiconductor package 300 may include a wide band gap semiconductor package with advanced semiconductor manufacturing. In some embodiments, the semiconductor package 300 may be produced or manufactured using advanced semiconductor packaging techniques as disclosed herein.

As illustrated in FIG. 3, the semiconductor package 300 includes a laminate 310, which may comprise an organic composite, in accordance with one embodiment. The semiconductor package 300 includes an interposer 320 disposed atop, or attached to, the laminate 310. In one or more embodiments, the interposer 320 may include silicon carbide.

As further illustrated in FIG. 3, the semiconductor package 300 includes a die 330 disposed atop, or attached to, the interposer 320. In one or more embodiments, the die 330 may include a radio frequency monolithic microwave integrated circuit. In one or more embodiments, the die 330 may be configured to operate in a range of frequency between 50 GHz and 150 GHz, between 70 GHz and 130 GHz, between 90GHz and 110GHz, or any frequence ranges therebetween.

In one or more embodiments, the interposer 320 may include a plurality of vias 325 (also referred to herein as hot vias), which are vertical through-vias across the thickness of the interposer 320. In various embodiments, the vias 325 are configured for electrical connections between the die 330 and the laminate 310, as shown in FIG. 3. In one or more embodiments, one or more of the vias 325 may be electrically connected to one or more hot vias (not shown) of the die 330.

As further illustrated in FIG. 3, the semiconductor package 300 includes a lid 340 attached to the interposer 320. In one or more embodiments, the lid 340 is attached to the interposer 320 via one or more legs 345 of the lid 340 in a configuration such that the attachment forms an encapsulation that encapsulates the die 330 therewithin. In one or more embodiments, the lid 340 may be attached to the interposer 320 in a configuration, as shown in FIG. 3, such that the attachment forms a cavity 305 that encapsulates the die 330 therewithin.

In one or more embodiments, the semiconductor package 300 includes one or more capacitive or passive components 350 electrically connected to the laminate 310. In one or more embodiments, the one or more capacitive or passive components 350 are surface-mounted technology (SMT) decoupling capacitors, radio frequency (RF) tuning capacitors, and/or other passive components. In one or more embodiments, the one or more capacitive or passive components 350 are disposed on the laminate 310 adjacent the interposer 320, as shown in FIG. 3. By placing the one or more capacitive or passive components 350 directly adjacent the interposer 320, the one or more capacitive or passive components 350 are integrated directly into the packaging of semiconductor device as shown in the semiconductor package 300, which eliminates the need to allocate separate board (e.g., PCB) space for decoupling capacitive or passive components, as they are now part of the semiconductor package 300 itself.

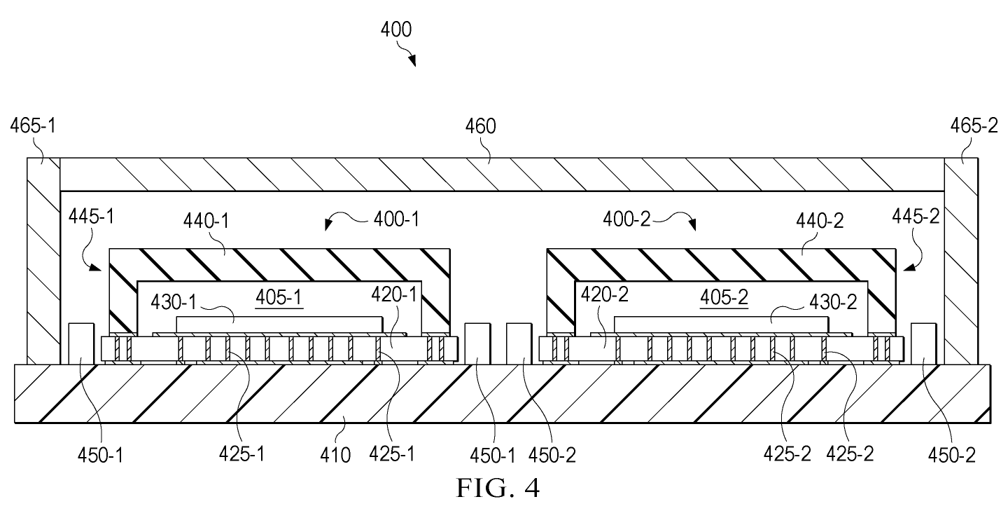

FIG. 4 illustrates a cross-sectional view of an example semiconductor package 400, according to aspects of the present disclosure. In one or more embodiments, the semiconductor package 400 may include a wide band gap semiconductor package with advanced semiconductor manufacturing. In some embodiments, the semiconductor package 400 may be produced or manufactured using advanced semiconductor packaging techniques as disclosed herein.

As illustrated in FIG. 4, the semiconductor package 400 includes a laminate 410, which may comprise an organic composite, in accordance with one embodiment. The semiconductor package 400 includes a first interposer 420-1 and a second interposer 420-2 (collectively may be referred to herein as interposers 420) disposed atop, or attached to, the laminate 410. In one or more embodiments, each of the interposers 420-1 and 420-2 may include silicon carbide. Although shown with two interposers 420-1 and 420-2 in FIG. 4, the semiconductor package 400 may include any number of interposers 420 within the semiconductor package 400.

As further illustrated in FIG. 4, the semiconductor package 400 includes a first die 430-1 and a second die 430-2 (collectively may be referred to herein as dies 430) disposed atop, or attached to, the respective first interposer 420-1 and second interposer 420-2. Although shown with two dies 430-1 and 430-2 in FIG. 4, the semiconductor package 400 may include any number of dies 430 within the semiconductor package 400. In one or more embodiments, the dies 430 may include a radio frequency monolithic microwave integrated circuit. In one or more embodiments, the dies 430 may be configured to operate in a range of frequency between 50GHz and 150GHz, between 70GHz and 130GHz, between 90GHz and 110 GHz, or any frequence ranges therebetween.

In one or more embodiments, the interposers 420-1 and 420-2 may include a plurality of vias 425-1 and 425-2 (collectively may be referred to herein as vias 425), respectively (also referred to herein as hot vias), which are vertical through-vias across the thickness of the interposers 420-1 and 420-2. In various embodiments, the vias 425-1 and 425-2 are configured for electrical connections between the dies 430 and the laminate 210, as shown in FIG. 4. In one or more embodiments, one or more of the vias 425-1 and 425-2 may be electrically connected to one or more hot vias (not shown) of the dies 430.

As further illustrated in FIG. 4, the semiconductor package 400 includes a first lid 440-1 and a second lid 440-2 (collectively may be referred to herein as lids 440) respectively attached to the first interposer 420-1 and the second interposer 420-2. In one or more embodiments, the first lid 440-1 is attached to the first interposer 420-1 via one or more legs 445-1 of the lid 440-1 in a configuration such that the attachment forms an encapsulation that encapsulates the first die 430-1 therewithin. Similarly, the second lid 440-2 is attached to the second interposer 420-2 via one or more legs 445-2 of the second lid 440-2 in a configuration such that the attachment forms an encapsulation that encapsulates the second die 430-2 therewithin, in one or more embodiments. In other words, the lids 440 may be attached to the interposers 420 in a configuration, as shown in FIG. 4, such that the attachment forms a respective first cavity 405-1 and a second cavity 405-2, which respectively encapsulates the first die 430-1 and the second die 430-2.

In one or more embodiments, the semiconductor package 400 includes one or more first capacitive or passive components 450-1 and one or more second capacitive or passive components 450-2 (collectively may be referred to herein as capacitive or passive components 450) electrically connected to the laminate 410. In one or more embodiments, the one or more capacitive or passive components 450 are surface-mounted technology (SMT) decoupling capacitors, radio frequency (RF) tuning capacitors, and/or other passive components. In one or more embodiments, the one or more capacitive or passive components 450 are disposed on the laminate 410 adjacent each of the interposers 420-1 and 420-2, as shown in FIG. 4. By placing the one or more capacitive or passive components 450 directly adjacent the interposers 420-1 and 420-2, the one or more capacitive or passive components 450 are integrated directly into the packaging of semiconductor device as shown in the semiconductor package 400, which eliminates the need to allocate separate board (e.g., PCB) space for decoupling capacitive or passive components, as they are now part of the semiconductor package 400 itself.

As further illustrated in FIG. 4, the semiconductor package 400 includes an electromagnetic interference (EMI) shield structure 460 that is attached to the laminate 410 via one or more legs 465-1 and 465-2 (collectively may be referred to herein as legs 465) of the EMI shield structure 460 such that the attachment forms an EMI shield that shields the dies 430 therewithin. As illustrated in FIG. 4, the EMI shield structure 460 forms an EMI shield that shields the first die 430-1 and the second die 430-2 via attachment of the legs 465-1 and 465-2 with the laminate 410. Thus, a single EMI shield structure 460 is configured to provide an EMI shield to both dies 430-1 and 430-2, in accordance with one or more embodiments. Although shown to shield only two dies 430-1 and 430-2 in FIG. 4, the EMI shield structure 460 may be configured to provide EMI shielding for any number of dies 430 within the semiconductor package 400. Thus, the disclosed implementation illustrated in FIG. 4 allows the entire semiconductor package 400, including the capacitive or passive components 450, to be covered by a single EMI shield structure 460, which can help reduce electromagnetic interference while improving signal integrity.

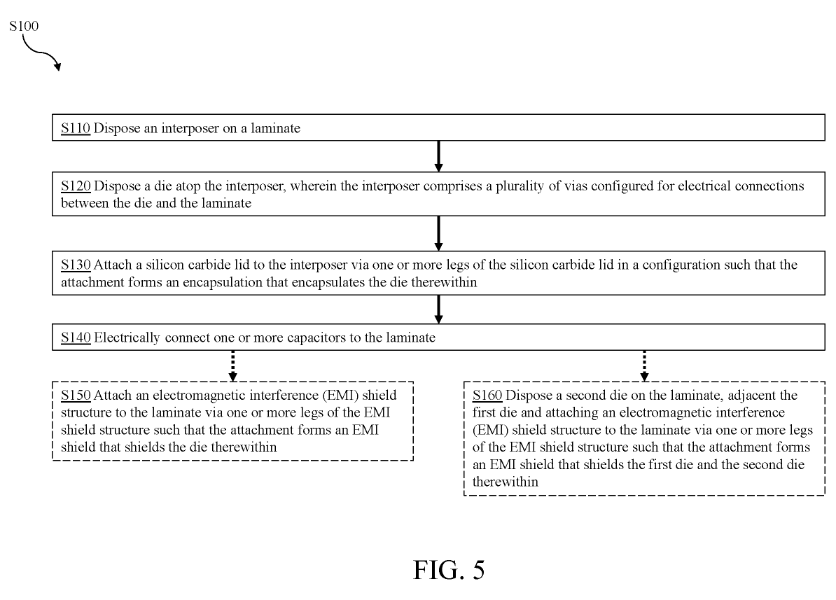

FIG. 5 illustrates a flowchart for a method S100 for preparing an example semiconductor package, according to aspects of the present disclosure. In one or more embodiments, the example semiconductor package prepared using the method S100 may include a semiconductor package, such as the semiconductor packages 100, 200, 300, and 400, as described with respect to FIGS. 1, 2, 3, and 4. Similar to the semiconductor packages 100, 200, 300, and 400, the example semiconductor package includes an on-package capacitive or passive components (e.g., SMT decoupled capacitive or passive components 150, 250, 350, and 450), according to aspects of the present disclosure. In one or more embodiments, a wireless device may include a semiconductor package, such as semiconductor packages 100, 200, 300, and 400, produced using the method S100 described herein.

As shown in FIG. 5, the method S100 for preparing the example semiconductor package includes, at step S110, disposing an interposer on a laminate. In one or more embodiments, the interposer may be an interposer, such as the interposers 120, 220, 230, or 240, and the laminate may be a laminate, such as the laminate 110, 210, 310, or 410, as described in FIGS. 1, 2, 3, and 4.

The method S100 further includes, at step S120, disposing a die atop the interposer, wherein the interposer comprises a plurality of vias configured for electrical connections between the die and the laminate. In one or more embodiments, the die may be a die, such as the dies 130, 230, 330, or 340, and the vias may be vias, such as the vias 125, 225, 325, or 425, as described in FIGS. 1, 2, 3, and 4. In one or more embodiments of the method S100, the die may include a radio frequency monolithic microwave integrated circuit configured to operate in a range of frequency between 50 GHz and 150 GHz.

The method S100 further includes, at step S130, attaching a lid to the interposer via one or more legs of the lid in a configuration such that the attachment forms an encapsulation that encapsulates the die therewithin. In one or more embodiments, the lid may be a lid, such as the lids 140, 240, 340, or 440, and the one or more legs includes legs, such as the legs 145, 245, 345, or 445, as described with respect to FIGS. 1, 2, 3, and 4.

The method S100 further includes, at step S140, electrically connecting one or more capacitive or passive components to the laminate. In one or more embodiments, the one or more capacitive or passive components may include capacitive or passive components, such as the capacitive or passive components 150, 250, 350, or 450, as described with respect to FIGS. 1, 2, 3, and 4. In one or more embodiments, one or more capacitive or passive components are surface-mounted technology (SMT) decoupling capacitors, radio frequency (RF) tuning capacitors, and/or other passive components.

In one or more embodiments of the method S100, electrically connecting one or more capacitive or passive components to the laminate comprises disposing the one or more capacitive or passive components atop the lid, and electrically connecting the one or more capacitive or passive components to the laminate via one or more electrical connections embedded within the one or more legs of the lid. In one or more embodiments, the one or more electrical connections may include electrical connections, such as the electrical connections 155 and 255, as described with respect to FIGS. 1 and 2. In one or more embodiments, the one or more electrical connections embedded within the one or more legs of the lid comprise conductive vias. In one or more embodiments, the conductive vias are formed within the one or more legs, through silicon vias, metal posts, or plated through-holes, etc.

In one or more embodiments of the method S100, the one or more capacitive or passive components are disposed on the laminate adjacent the interposer.

In one or more embodiments, the method S100 further includes optionally, at step S150, attaching an electromagnetic interference (EMI) shield structure to the laminate via one or more legs of the EMI shield structure such that the attachment forms an EMI shield that shields the die therewithin. In such embodiments, the one or more capacitive or passive components are disposed atop the lid and are electrically connected to the laminate via one or more electrical connections embedded within the one or more legs of the lid.

In one or more embodiments, the method S100 further includes optionally, at step S160, disposing a second die on the laminate, adjacent the first die and attaching an electromagnetic interference (EMI) shield structure to the laminate via one or more legs of the EMI shield structure such that the attachment forms an EMI shield that shields the first die and the second die therewithin. In such embodiments of the method S100, the one or more capacitive or passive components are disposed on the laminate adjacent the interposer.

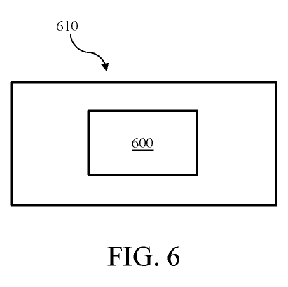

FIG. 6 illustrates an electronic device or a wireless device 610 comprising a semiconductor package 600, according to aspects of the present disclosure. In some implementations, the electronic device or wireless device 610 may include, for example, but not limited to, a computer, a cellular device, a satellite communication device, a wi-fi device, a radar, a global position system device, or any wireless device. In one or more embodiments, the semiconductor package 600 may include a semiconductor package, such as the semiconductor packages 100, 200, 300, and 400, as described with respect to FIGS. 1, 2, 3, and 4. The semiconductor package 600 may implement any RF component used in wireless applications, as an example, such as one or more RF power amplifiers or in a radar or radar systems; and the semiconductor package 600 may be coupled to other circuitry for implementing a wireless application.

In one or more embodiments, the semiconductor package 600 of the wireless device 610 includes a die disposed on a laminate; an interposer disposed between the die and the laminate, the interposer comprising a plurality of vias configured for electrical connections between the die and the laminate; a lid attached to the interposer via one or more legs of the lid in a configuration such that the attachment forms an encapsulation that encapsulates the die therewithin; and one or more capacitive or passive components electrically connected to the laminate. In one or more embodiments, the capacitive or passive components include surface-mounted technology (SMT) decoupling capacitors, radio frequency (RF) tuning capacitors, and/or other passive components.

In one or more embodiments of the semiconductor package 600 of the wireless device 610, the interposer may be an interposer, such as the interposers 120, 220, 230, or 240, the laminate may be a laminate, such as the laminate 110, 210, 310, or 410, the die may be a die, such as the dies 130, 230, 330, or 340, and the vias may be vias, such as the vias 125, 225, 325, or 425, as described in FIGS. 1, 2, 3, and 4. In one or more embodiments of the semiconductor package 600 of the wireless device 610, the die may include a radio frequency monolithic microwave integrated circuit configured to operate in a range of frequency between 50 GHz and 150 GHz.

In one or more embodiments of the semiconductor package 600 of the wireless device 610, the lid may be a lid, such as the lids 140, 240, 340, or 440, and the one or more legs includes legs, such as the legs 145, 245, 345, or 445, as described with respect to FIGS. 1, 2, 3, and 4. In one or more embodiments of the semiconductor package 600 of the wireless device 610, the one or more capacitive or passive components may include capacitive or passive components, such as the capacitive or passive components 150, 250, 350, or 450, the one or more electrical connections may include electrical connections, such as the electrical connections 155 and 255, as described with respect to FIGS. 1 and 2.

In one or more embodiments of the semiconductor package 600 of the wireless device 610, the one or more capacitive or passive components are disposed atop the lid and are electrically connected to the laminate via one or more electrical connections embedded within the one or more legs of the lid.

In one or more embodiments of the wireless device 610, the semiconductor package 600 further includes an electromagnetic interference (EMI) shield structure attached to the laminate via one or more legs of the EMI shield structure such that the attachment forms an EMI shield that shields the die therewithin. In one or more embodiments of the wireless device 610, the semiconductor package 600 further includes a second die disposed on the laminate, adjacent the first die, such that the electromagnetic interference (EMI) shield structure attached to the laminate forms an EMI shield that shields the first die and the second die therewithin. In such embodiments of the wireless device 610, the capacitive or passive components are disposed on the laminate adjacent the interposer.

Persons skilled in the art will recognize that the apparatus, systems, and methods described above can be modified in various ways. Accordingly, persons of ordinary skill in the art will appreciate that the embodiments encompassed by the present disclosure are not limited to the particular exemplary embodiments described above. In that regard, although illustrative embodiments have been shown and described, a wide range of modification, change, and substitution is contemplated in the foregoing disclosure. It is understood that such variations may be made to the foregoing without departing from the scope of the present disclosure. Accordingly, it is appropriate that the appended claims be construed broadly and in a manner consistent with the present disclosure.

1. A semiconductor package comprising:
a die disposed on a laminate;
an interposer disposed between the die and the laminate, the interposer comprising a plurality of vias configured for electrical connections between the die and the laminate;
a lid attached to the interposer via one or more legs of the lid in a configuration such that the attachment forms an encapsulation that encapsulates the die therewithin; and
one or more capacitive or passive components electrically connected to the laminate.

2. The semiconductor package of claim 1, wherein the one or more capacitive or passive components are surface-mounted technology (SMT) decoupling capacitors, radio frequency (RF) tuning capacitors, and/or other passive components.

3. The semiconductor package of claim 1, wherein the one or more capacitive or passive components are disposed atop the lid and are electrically connected to the laminate via one or more electrical connections embedded within the one or more legs of the lid.

4. The semiconductor package of claim 3, wherein the one or more electrical connections embedded within the one or more legs of the lid comprise conductive vias.

5. The semiconductor package of claim 1, wherein the one or more capacitive or passive components are disposed on the laminate adjacent the interposer.

6. The semiconductor package of claim 1, further comprising:
an electromagnetic interference (EMI) shield structure attached to the laminate via one or more legs of the EMI shield structure such that the attachment forms an EMI shield that shields the die therewithin.

7. The semiconductor package of claim 6, wherein the one or more capacitive or passive components are disposed atop the lid and are electrically connected to the laminate via one or more electrical connections embedded within the one or more legs of the lid.

8. The semiconductor package of claim 1, wherein the die is a first die, the semiconductor package further comprises:
a second die disposed on the laminate, adjacent the first die; and
an electromagnetic interference (EMI) shield structure attached to the laminate via one or more legs of the EMI shield structure such that the attachment forms an EMI shield that shields the first die and the second die therewithin, wherein the one or more capacitive or passive components are disposed on the laminate adjacent the interposer.

9. A method for preparing a semiconductor package, comprising:
disposing an interposer on a laminate;
disposing a die atop the interposer, wherein the interposer comprises a plurality of vias configured for electrical connections between the die and the laminate;
attaching a lid to the interposer via one or more legs of the lid in a configuration such that the attachment forms an encapsulation that encapsulates the die therewithin; and
electrically connecting one or more capacitive or passive components to the laminate.

10. The method of claim 9, wherein the one or more capacitive or passive components are surface-mounted technology (SMT) decoupling capacitors, radio frequency (RF) tuning capacitors, and/or other passive components.

11. The method of claim 9, wherein electrically connecting one or more capacitive or passive components to the laminate comprises:
disposing the one or more capacitive or passive components atop the lid, and
electrically connecting the one or more capacitive or passive components to the laminate via one or more electrical connections embedded within the one or more legs of the lid.

12. The method of claim 11, wherein the one or more electrical connections embedded within the one or more legs of the lid comprise conductive vias.

13. The method of claim 9, wherein the one or more capacitive or passive components are disposed on the laminate adjacent the interposer.

14. The method of claim 9, further comprising:
attaching an electromagnetic interference (EMI) shield structure to the laminate via one or more legs of the EMI shield structure such that the attachment forms an EMI shield that shields the die therewithin.

15. The method of claim 14, wherein the one or more capacitive or passive components are disposed atop the lid and are electrically connected to the laminate via one or more electrical connections embedded within the one or more legs of the lid.

16. The method of claim 9, wherein the die is a first die, the method further comprises:
disposing a second die on the laminate, adjacent the first die; and
attaching an electromagnetic interference (EMI) shield structure to the laminate via one or more legs of the EMI shield structure such that the attachment forms an EMI shield that shields the first die and the second die therewithin.

17. A wireless device comprising a semiconductor package, wherein the semiconductor package comprises:
a die disposed on a laminate;
an interposer disposed between the die and the laminate, the interposer comprising a plurality of vias configured for electrical connections between the die and the laminate;
a lid attached to the interposer via one or more legs of the lid in a configuration such that the attachment forms an encapsulation that encapsulates the die therewithin; and
one or more surface-mounted technology (SMT) decoupling capacitors, radio frequency (RF) tuning capacitors, and/or other passive components electrically connected to the laminate.

18. The wireless device of claim 17, wherein the one or more capacitive or passive components are disposed atop the lid and are electrically connected to the laminate via one or more electrical connections embedded within the one or more legs of the lid.

19. The wireless device of claim 17, wherein the semiconductor package further comprises:
an electromagnetic interference (EMI) shield structure attached to the laminate via one or more legs of the EMI shield structure such that the attachment forms an EMI shield that shields the die therewithin.

20. The wireless device of claim 17, wherein the die is a first die, the semiconductor package further comprises:
a second die disposed on the laminate, adjacent the first die; and
an electromagnetic interference (EMI) shield structure attached to the laminate via one or more legs of the EMI shield structure such that the attachment forms an EMI shield that shields the first die and the second die therewithin, wherein the one or more capacitive or passive components are disposed on the laminate adjacent the interposer.
